(19) United States
(12) Patent Application Publication
(10) Pub. No.: US 2011/0000518 A1
(43) Pub. Date: Jan. 6, 2011

(54) LAYERED ARTICLE

(75) Inventors: Tomoki KOJIMA, Ichihara-shi (JP); Jinsho NAMBU, Kamakura-shi (JP)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: SUMITOMO CHEMICAL COMPANY, LIMITED, Tokyo (JP)

(21) Appl. No.: 12/825,568

(22) Filed: Jun. 29, 2010

(30) Foreign Application Priority Data
Jul. 1, 2009 (JP) 2009-156628
Aug. 26, 2009 (JP) 2009-195305
Dec. 21, 2009 (JP) 2009-289080

(51) Int. Cl. H01L 31/042; B32B 5/16

(52) U.S. Cl. 136/244; 428/331

(57) ABSTRACT

There is provide a layered article with good snow sliding property and antifouling property, article having a substrate and a particle layer laminated on the substrate, wherein the particle layer is a layer formed by applying a particle dispersion liquid to the substrate, the particle dispersion liquid comprising first silicon oxide particles composed of branched rod-shaped particles, each of the branched rod-shaped particles having a diameter of 3 to 50 nm and the branched rod-shaped particles having an average particle diameter of 30 to 500 nm, second silicon oxide particles having an average particle diameter of 1 to 20 nm, third silicon oxide particles having an average particle diameter of greater than 20 mn, and a dispersion medium, wherein the content of the first silicon oxide particles is 15 to 50% by weight, the content of the second silicon oxide particles is 15 to 50% by weight, and the content of the third silicon oxide particles is 35 to 70% by weight where the total amount of the first, second and third silicon oxide particles is 100% by weight, and then removing the dispersion medium from the applied particle dispersion liquid.

### CROSS-REFERENCE TO RELATED APPLICATIONS

This application is entitled to and claims the benefits of the priority pursuant to 35 U.S.C. §119(a) of Japanese Patent Application Nos. 2009-156628 filed Jul. 1, 2009, 2009-195305 filed Aug. 26, 2009, and 2009-289080 filed Dec. 21, 2009. The entire disclosures of all of the above applications are hereby incorporated herein by reference.

### TECHNICAL FIELD

The present invention relates to layered articles which are excellent in snow sliding property and antifouling property.

### DESCRIPTION OF THE RELATED ART

Materials used in residences, warehouses, buildings, transport instruments, road/railroad-related facilities, agricultural facilities, solar panels, overhead power transmission facilities, and so on are required to be hardly fouled even if they are used outdoors for a long period of time. Moreover, when such materials are used in snow areas, such problems as collapse, breakage, and deformation caused by a snow load will arise and therefore it is required that snow is hardly accumulated on the material, in other words, the material is required to have snow sliding property.

Various techniques have been devised for the purpose of imparting antifouling property or snow sliding property to materials. For example, JP 2003-155348 A discloses a method for preventing adhesion of snow and ice by using a polysiloxane having a perfluoroalkyl group or a composition thereof.

JP 2006-111680 A discloses a coating composition for forming a film for snow sliding using photocatalytic microparticles and colloidal silica, a film for snow sliding, and a component for snow sliding.

JP 2006-9452 A discloses a snow sliding sheet obtained by forming an infrared absorptive layer on a surface of a woven fabric cloth prepared by weaving drawn thermoplastic resin yarn, and forming an infrared reflective layer on the opposite surface.

Although the method disclosed in JP 2003-155348 A is a technology to make snow slip by imparting water repellency, original water repellency is lost gradually through fouling with time, and therefore it was difficult to continue to develop snow sliding property and antifouling property for a long time. Regarding a method of using photocatalytic microparticles which are hydrophilized by ultraviolet rays as disclosed in JP 2006-111680 A and a method of using an infrared absorbing agent as disclosed in JP 2006-9452 A, since the amount of ultraviolet rays or infrared rays would decrease with increase of snowfall, there was a problem that inherent functions could not be exhibited and therefore snow sliding property and antifouling property would become insufficient. Thus, the conventional technologies were insufficient in snow sliding property and antifouling property. An object of the present invention is to provide a layered article excellent in snow sliding property and antifouling property.

### SUMMARY OF THE INVENTION

In one aspect, the present invention is directed to a layered article comprising a substrate and a particle layer laminated on the substrate,

wherein the particle layer is a layer formed by applying a particle dispersion liquid to the substrate, the particle dispersion liquid comprising:

first silicon oxide particles composed of branched rod-shaped particles, each of the branched rod-shaped particles having a diameter of 3 to 50 nm and the branched rod-shaped particles having an average particle diameter of 30 to 500 nm,

second silicon oxide particles having an average particle diameter of 1 to 20 nm,

third silicon oxide particles having an average particle diameter of greater than 20 nm, and

a dispersion medium,

wherein the content of the first silicon oxide particles is 15 to 50% by weight, the content of the second silicon oxide particles is 15 to 50% by weight, and the content of the third silicon oxide particles is 35 to 70% by weight where the total amount of the first, second and third silicon oxide particles is 100% by weight, and then removing the dispersion medium from the applied particle dispersion liquid.

In one preferred embodiment of the layered article, the particle layer has a water contact angle of 5° or smaller. In another preferred embodiment, the substrate is a film made of a thermoplastic resin. In another preferred embodiment, the substrate is a signboard for outdoor use. In another preferred embodiment, the substrate is glass.

In another aspect, the present invention is directed to a solar panel having a light receiving surface, wherein the light receiving surface is composed of the above-mentioned layered article with the particle layer exposed to the outside of the solar panel. In this embodiment, the substrate of the layered article is glass.

The above-mentioned layered article of the present invention can be considered to be equivalent to a layered article comprising a substrate and a particle layer laminated on the substrate,

wherein the particle layer comprises:

first silicon oxide particles composed of branched rod-shaped particles, each of the branched rod-shaped particles having a diameter of 3 to 50 nm and the branched rod-shaped particles having an average particle diameter of 30 to 500 nm,

second silicon oxide particles having an average particle diameter of 1 to 20 nm, and

third silicon oxide particles having an average particle diameter of greater than 20 nm,

wherein the content of the first silicon oxide particles is 15 to 50% by weight, the content of the second silicon oxide particles is 15 to 50% by weight, and the content of the third silicon oxide particles is 35 to 70% by weight where the total amount of the first, second and third silicon oxide particles in the particle layer is 100% by weight.

According to the present invention, it is possible to form a layered article excellent in snow sliding property and antifouling property.

### DESCRIPTION OF THE PREFERRED EMBODIMENTS

The material to constitute the substrate in the present invention is not particularly restricted and a material appropriately selected from among conventional materials including thermosetting resins, thermoplastic resins, photocurable resins, fiber-reinforced plastics, metals, glass, ceramic materials for building, and so on may be used. For example, the light receiving surface of a solar panel is usually made of glass. Therefore, a layered article of the present invention that has a glass substrate as its substrate can be applied suitably to a light receiving part of a solar panel.

The substrate in the present invention is not particularly restricted in shape and may be in the form of film, sheet, board, and the like. In the present invention, films, sheets, and boards may be hereinafter collectively called film analogues.

As a substrate made of resin, a film analogue produced by shaping a thermoplastic resin by such a method as melt extrusion forming may be used and also a woven fabric film analogue produced by weaving filiform resin may be used, for example. Examples of the thermoplastic resin for constituting the substrate include olefin-based resins, e.g., homopolymers of α-olefins, such as ethylene and propylene, copolymers to be produced by copolymerizing two or more kinds of α-olefins, such as ethylene/propylene copolymers, ethylene/butene-1 copolymers, ethylene/4-methyl-1-pentene copolymers, ethylene/hexene-1 copolymers, and ethylene/octene-1 copolymers, copolymers which contain an α-olefin as a main component and are produced by copolymerizing an α-olefin and another monomer, such as ethylene/vinyl acetate copolymers, ethylene/acrylic acid copolymers, ethylene/methyl methacrylate copolymers, ethylene/vinyl acetate/methyl methacrylate copolymers, and ionomer resins, copolymers to be produced by copolymerizing an α-olefin and a vinyl group-containing aromatic monomer, such as ethylene/styrene copolymers, and copolymer produced by copolymerizing an α-olefin and a cyclic monomer, such as ethylene/norbornene copolymers, and ethylene/styrene/norbornene copolymers; chlorine-containing resins, such as polyvinyl chloride, vinyl chloride/methyl methacrylate copolymers, and polyvinylidene chloride; polyester resins, such as polyethylene terephthalate and polyethylene naphthalate; acrylic resins, such as poly(methyl methacrylate); cellulose-based resins, such as cellophane, triacetylcellulose, diacetylcellulose, and acetylcellulose butyrate; fluorine-containing resins; polyamide resins; and polycarbonate resins. As regards thermoplastic resins, a single resin may be used or alternatively two or more resins may be used in combination. Films made of thermoplastic resins are suitable as a substrate of a layered article to be used, for example, as an agricultural film because of their excellent flexibility.

Examples of the thermosetting resin for constituting the substrate include melamine resins and phenol resins.

Examples of the photocurable resin for constituting the substrate include acrylic resins and epoxy resins.

Examples of a fiber-reinforced plastic which can be used as a substrate include glass fiber-reinforced plastics (GFRP), continuous glass fiber-reinforced plastics (GMT), carbon fiber-reinforced plastics (CFRP), aramid fiber-reinforced plastics (AFRP), ZYLON fiber-reinforced plastics (ZFRP), and polyethylene fiber-reinforced plastics (DFRP).

Glass which can be used as a substrate is not particularly restricted and a glass sheet appropriately selected from among conventional glass sheets may be used.

It is simple and convenient to use a soda-lime glass that is good in smoothness and less in distortion of a transmission image, has stiffness of a certain degree thereby being less in distortion by wind or external force, is superior in visible light transmission, is produced by a float process at a relatively low cost, is less in coloring components, such as metal oxides, and is called a transparent type or a clear type.

Metal which can be used as a substrate is not particularly restricted and a material appropriately selected from among conventional metallic materials for building may be used.

The metallic materials for building include rolled steel and metal plates. Examples of the rolled steel include H-steel, round shaped steel pipes, square shaped steel pipes, angle steel, and I-steel. Examples of the metal plates include metal-plated steel plates, such as zinc-plated steel plates, Galvalume steel plates, and Gahan steel plates, color steel plates resulting from painting metal-plated steel plates for imparting design, stainless steel plates, and copper plates.

When the substrate in the present invention is a film or a sheet, the thickness thereof is usually 10 to 2000 μm. The substrate in the present invention may have either a single layer or multiple layers.

The layered article of the present invention is a layered article comprising a substrate and a particle layer laminated on the substrate,

wherein the particle layer is a layer formed by applying a particle dispersion liquid to the substrate, the particle dispersion liquid comprising:

first silicon oxide particles composed of branched rod-shaped particles, each of the branched rod-shaped particles having a diameter of 3 to 50 nm and the branched rod-shaped particles having an average particle diameter of 30 to 500 nm,

second silicon oxide particles having an average particle diameter of 1 to 20 nm,

third silicon oxide particles having an average particle diameter of greater than 20 nm, and

a dispersion medium,

wherein the content of the first silicon oxide particles is 15 to 50% by weight, the content of the second silicon oxide particles is 15 to 50% by weight, and the content of the third silicon oxide particles is 35 to 70% by weight where the total amount of the first, second and third silicon oxide particles is 100% by weight, and then removing the dispersion medium from the applied particle dispersion liquid.

The first silicon oxide particles are branched rod-shaped particles, each of the branched rod-shaped particles having a diameter of 3 to 50 nm and the branched rod-shaped particles having an average particle diameter of 30 to 500 nm. As such first silicon oxide particles, there can be used commercially available products, examples of which include SNOWTEX (registered trademark) UP and SNOWTEX OUP produced by Nissan Chemical Industries, Ltd., which are silica sols containing water as a dispersion medium, and IPA-ST-UP produced by Nissan Chemical Industries, Ltd., which is silica sol containing isopropanol as a dispersion medium. The diameter of each of the rod-shaped particles constituting the first silicon oxide particles (i.e., the diameter of each silicon oxide rod constituting the first silicon oxide particles) is determined from an image of the rod-shaped particle observed by using a transmission electron microscope.

The first silicon oxide particles are not necessarily needed to be the same in shape, but they are common in that they are in a thin long shape and have a branch. Examples of the shape of the first silicon oxide particles include an almost straight shape, a crooked shape, and a reticular shape composed of linked branches. The size of thin long silicon oxide particles is properly indicated by an average particle diameter measured by a dynamic light scattering method. In the present invention, the average particle diameter of the first silicon oxide particles is determined by the dynamic light scattering method. The measuring method of an average particle diameter by the dynamic light scattering method is explained in The Journal of Chemical Physics, Vol. 57, No. 11 (December, 1972), p. 4814, and an average particle diameter can be measured easily, for example, by using a commercially available device called N4 manufactured by Coulter.

The second silicon oxide particles in the present invention are silicon oxide particles having an average particle diameter of 1 to 20 nm, preferably 1 to 10 nm. The average particle diameter of the second silicon oxide particles is determined by a Sears method. The measurement of an average particle diameter by a Sears method is disclosed in Analytical Chemistry vol. 28, p. 1981-1983, 1956, and this method is applied to the measurement of the average particle diameter of the second silicon oxide particles. The second silicon oxide particles are preferably spherical particles.

As such second silicon oxide particles, there can be used commercially available products, examples of which include SNOWTEX (registered trademark) XS, OXS, S, OS, O, N, C, and AK produced by Nissan Chemical Industries, Ltd., which are silica sols containing water as a dispersion medium.

The third silicon oxide particles in the present invention are silicon oxide particles having an average particle diameter of greater than 20 nm, preferably 60 to 200 nm. The average particle diameter of the third silicon oxide particles is determined by a BET method. Specifically, the determination of the average particle diameter of the third silicon oxide particles by the BET method is performed by measuring a BET specific surface area S of the particles by the method disclosed in “Adsorption, Surface Area and Porosity,” Academic Press, London (1982), Chap. 2, p. 42, and then calculating a value of D by using a formula D=6/(ρ×S) where ρ is the density of the particles. The D calculated is the average particle diameter. The third silicon oxide particles are preferably spherical particles.

As such third silicon oxide particles, there can be used commercially available products, examples of which include SNOWTEX (registered trademark) XL, YL, and ZL produced by Nissan Chemical Industries, Ltd., which are silica sols containing water as a dispersion medium.

Regarding the proportions of the first silicon oxide particles, the second silicon oxide particles, and the third silicon oxide particles, the first silicon oxide particles account for 15 to 50% by weight, the second silicon oxide particles account for 15 to 50% by weight, and the third silicon oxide particles account for 35 to 70% by weight, where the total amount of these silicon oxide particles in the layer containing these particles is 100% by weight.

The aforementioned first, second, and third silicon oxide particles each can be obtained in the form of a particle dispersion liquid (sol). The layered article of the present invention can be produced by applying a mixed particle dispersion liquid prepared by mixing the aforementioned particle dispersion liquids (sols) to a substrate and then removing a liquid dispersion medium from the applied mixed particle dispersion liquid by proper means to form a layer.

The thickness of a layer to be formed on a substrate, which is not particularly limited, is preferably adjusted to 50 to 200 nm and it is more preferably adjusted to 80 to 150 nm in order to make stable snow sliding property and high antifouling property be developed. The thickness of the layer can be adjusted by changing the amounts of the first silicon oxide particles, the second silicon oxide particles, and the third silicon oxide particles contained in the mixed particle dispersion liquid or the applied amount of the mixed particle dispersion liquid.

The mixed particle dispersion liquid may contain a surfactant, an organic electrolyte, an inorganic layered compound, or the like.

Examples of the surfactant include various types of surfactants, such as anionic, cationic, nonionic, or amphoteric surfactants. Specifically, the anionic surfactants include sodium caprylate, potassium caprylate, sodium decanoate, sodium caproate, sodium myristate, potassium oleate, tetramethylammonium stearate, and sodium stearate, and alkali metal salts of carboxylic acids with an alkyl chain having from 6 to 10 carbon atoms are preferred.

Examples of the cationic surfactants include cetyltrimethylammonium chloride, dioctadecyldimethylammonium chloride, N-octadecylpyridinium bromide, and cetyltriethylphosphonium bromide.

Examples of the nonionic surfactants include sorbitan esters of fatty acids and glycerol esters of fatty acids.

The organic electrolyte refers to an organic compound that has an ionizing ionic group. Examples thereof include sodium p-toluenesulfonate, sodium benzenesulfonate, potassium butylsulfonate, sodium phenylphosphinate, and sodium diethylphosphate, and in particular, benzenesulfonic acid derivatives are preferred. Among organic electrolytes, one that exhibits a high surface activating effect may be called a surfactant.

The inorganic layered compound is an inorganic compound with a layer structure made of unit crystal layers piled one on another and preferably has a particle diameter of 5 μm or less. In particular, from the viewpoint of transparency, the particle diameter is preferably 3 μm or less.

As the inorganic layered compound, a compound which is swollen or cleaved with a dispersion medium contained in a mixed particle dispersion liquid is preferred, and in particular, a clay mineral having swellability is preferred. The clay minerals are classified to compounds having a two-layer structure in which an octahedral layer containing a central metal, such as aluminum and magnesium, is disposed on a silica tetrahedral layer, and compounds having a three-layer structure in which two silica tetrahedral layers sandwich therebetween an octahedral layer containing a central metal, such as aluminum and magnesium. The former type of compounds include kaolinite series, antigorite series, and so on, and the latter type of compounds include smectite series, vermiculite series, mica series, and so on depending on the number of interlayer cations. In particular, smectite series which are characterized by exhibiting thixotropic viscosity when being dispersed in water are preferred. The viscosity of a mixed particle dispersion liquid can be controlled by mixing an inorganic layered compound to the dispersion liquid, and the control of viscosity by mixing of such an inorganic layered compound has an effect of improving application workability and fixability of the dispersion liquid to a substrate made of resin.

A method of applying the mixed particle dispersion liquid to a substrate is not particularly restricted, and the liquid can be applied by such conventional methods as gravure coating, reverse coating, brush roll coating, spray coating, kiss coating, die coating, dipping, and bar coating.

By removing a liquid dispersion medium from a dispersion liquid layer formed by applying a mixed particle dispersion liquid to a substrate, a particle layer can be formed. An example of the method for removing the liquid dispersion medium from the dispersion liquid layer is a method of heating under normal pressure or reduced pressure. The pressure and the heating temperature to be used in the removal of the liquid dispersion medium may be chosen appropriately according to the materials to be used (that is, the first silicon oxide particles, the second silicon oxide particles, the third silicon oxide particles, and the liquid dispersion medium). For example, when the dispersion medium is water, drying may be done generally at 50 to 80° C., preferably at about 60° C.

If the substrate is one having heat resistance, such as glass and ceramics, it is possible to further increase adhesiveness to the substrate by performing baking treatment after the application of the dispersion liquid.

It is preferable to apply a pretreatment, such as corona treatment, ozonization, plasma treatment, flame treatment, electron beam treatment, anchor coat treatment, and rinsing, to a surface of the substrate prior to the application of the mixed particle dispersion liquid to the substrate.

It is preferable to form a base coating layer by applying a liquid containing colloidal alumina, colloidal silica, an anionic surfactant, and an inorganic layered compound like that disclosed in JP 08-319476 A to a substrate as a pre-treatment of the substrate, and the substrate provided with the base coating layer may be used as the substrate in the present invention.

The layered article of the present invention should just have a layer containing the first silicon oxide particles, the second silicon oxide particles, and the third silicon oxide particles at least on one side of the substrate. When the layered article of the present invention has the aforementioned layer on one side, it is beneficial to use it so that the layer may serve as a layer to be required to have antifouling property or snow sliding property. For example, when using the layered article of the present invention outdoors, it is recommended to use the article while arranging it so that its layer containing the first silicon oxide particles, the second silicon oxide particles, and the third silicon oxide particles may come into contact with rain or snow directly.

The layered article of the present invention can be used suitably for covering materials needed to have durability or easy applicability, such as covering materials for agricultural houses, cattle houses, simple warehouses, garages, all-weather sport facilities, residences, warehouses, buildings, transport instruments, bridges, road/railroad-related facilities, overhead power transmission facilities, solar panels, and ceramic materials for building, e.g., roof tiles, slates, and tiles. Moreover, since the layered article of the present invention excels in antifouling property, it is suitable for outdoor signboard applications with importance in appearance, such as road signs. In a layered article of the present invention to be used as an outdoor signboard, its substrate is an outdoor signboard. Since the layered article of the present invention excels also in transparency, it is suitable for use in which lighting property is highly required, for example, use as a covering material of an agricultural house.

Moreover, the layered article of the present invention excels also in hydrophilicity because it has a layer containing the first silicon oxide particles, the second silicon oxide particles, and the third silicon oxide particles with the layer forming a surface of the article. In the layered article of the present invention, the water contact angle of the layer containing the first silicon oxide particles, the second silicon oxide particles, and the third silicon oxide particles is preferably 5° or less, and more preferably 3° or less. Since the layered article of the present invention has hydrophilicity, it can exhibit an air conditioning function easily by applying watering treatment to a surface of the layered article and therefore it can be expected to have an effect of preventing overheating of a lighting material.

When the layered article of the present invention is used as an agricultural film, it preferably has a thickness of 50 to 200 μm. When the layered article of the present invention is used as a covering material to be used for a long time period of a cattle house, a simple warehouse or a garage, the thickness of the layered article is preferably 50 to 2000 μm.

One preferable application of the layered article of the present invention is a solar panel having a light receiving surface, wherein the light receiving surface is composed of the laminated article of the present invention with the particle layer exposed to the outside of the solar panel. In this case, a substrate made of glass is suitably employed as the substrate of the layered article.

When the layered article of the present invention is used as an agricultural film or a component of a solar panel, the layered article having a particle layer preferably has a total light transmittance of 50% or more, preferably 80% or more for securing satisfactory transparency.

### Examples

The present invention will be described in detail below with reference to Examples, to which the present invention is not limited.

### [Substrate]

A low density polyethylene film of 100 μm in thickness produced by blown film forming was used as substrate A.
A float glass sheet of 6 mm in thickness was used as substrate B.
A color painted zinc-plated steel sheet was used as substrate C.
Au acrylic sheet of 2 mm in thickness was used as substrate D.

### [Preparation of Base Coating Liquid]

An inorganic layered compound dispersion liquid was prepared by mixing and stirring 99% by weight of ion exchange water and 1% by weight of an inorganic layered compound (commercial name: Sumecton SA, produced by KUNIMINE INDUSTRIES CO., LTD.).

Then, a base coating liquid was prepared by mixing and stirring 79.584% by weight of ion exchange water, 9.000% by weight of the above-mentioned inorganic layered compound dispersion liquid, 9.000% by weight of colloidal alumina aqueous dispersion liquid (commercial name: ALUMINA SOL 520; average particle diameter: 20 nm; solid concentration: 20% by weight; produced by Nissan Chemical Industries, Ltd.), 2.400% by weight of colloidal silica aqueous dispersion liquid (commercial name: SNOWTEX 20; average particle diameter: 20 nm; solid concentration; 20% by weight; produced by Nissan Chemical Industries, Ltd.), 0.014% by weight of sodium caprylate (reagent grade, produced by Tokyo Chemical Industry Co., Ltd.), and 0.002% by weight of sodium p-toluenesulfonate (reagent grade, produced by Nacalai Tesque, Inc.).

### [Preparation of Mixed Particle Dispersion Liquid]

A mixed particle dispersion liquid was prepared by mixing silicon oxide particles (A), silicon oxide particles (B), and silicon oxide particles (C) in the proportions given in Table 1 so that the solid concentration would become 5% by weight. Primary materials used are as follows.

### 1) Silicon Oxide Particles (A)

SNOWTEX (registered trademark) UP (branched rod-like colloidal silica produced by Nissan Chemical Industries, Ltd.; diameter of each branched rod-like particle: 5 to 20 nm, which was determined by a transmission electron microscopic observation; average particle diameter determined by a dynamic light scattering method: 40 to 300 nm; solid concentration; 20% by weight). This is hereinafter referred to as “ST-UP.”

### 2) Silicon Oxide Particles (B)

SNOWTEX (registered trademark) ST-XS (colloidal silica produced by Nissan Chemical Industries, Ltd.; average particle diameter determined by a Sears method: 4 to 6 nm; solid concentration: 20% by weight). This is hereinafter referred to as “ST-XS.”

### 3) Silicon Oxide Particles (C)

SNOWTEX (registered trademark) ST-ZL (colloidal silica produced by Nissan Chemical Industries, Ltd.; average particle diameter determined by a BET method: 78 nm; solid concentration: 40% by weight). This is hereinafter referred to as “ST-ZL.”

### [Formation of Base Coating Layer]

A base coating liquid was applied to a surface of a substrate with a #16 Meyer bar and then was dried, so that a layer of base coating was formed. The estimated thickness of the base coating layer just after the application was 37 μm. The drying was carried out with a drier.

### [Formation of Silicon Oxide Particle Layer]

A mixed particle dispersion liquid was further applied with a #16 Meyer bar to the base coating liquid formed above and then was dried, so that a silicon oxide particle layer was formed. Thus, a film for outdoor spreading was obtained. The estimated thickness of the silicon oxide particle layer just after the application was 37 μm. The drying was carried out with a drier.

### [Evaluation of Layered Article]

Evaluations in Examples were carried out by the following methods.

### 1) Coefficient of Dynamic Friction of Snow

A snow block (packed snow of 12 cm×12 cm in size, snow load: 20 kg/m³) prepared by molding natural snow was placed on a sample and, after a prescribed time period, it was made slip a distance of 15 cm at a rate of 5 mm/sec to measure a slip resistance. A value obtained by dividing the slip resistance by the weight of the snow was defined as a coefficient of dynamic friction. In the measurement, a snow block was set at −10° C., and then the room temperature was raised to +5° C. At a time after a lapse of one hour, for which some snowmelt generated (i.e., the friction interface was wetted), and every one hour thereafter, measurement was carried out four times in total. Measurement was repeated three times under the same conditions, and an average of the measurements was calculated and the results are provided in Tables 1, 3, 6, and 8.

### 2) Wettability

In a thermostatic chamber of 23° C., 3 μl of pure water was dropped to a surface of a sample, and then a contact angle was measured with an automatic contact angle analyzer, Model CA-Z, manufactured by Kyowa Interface Science Co., LTD. The results are given in Tables 1, 3, 6, and 8.

### 3) Gloss

A gloss was measured at a measuring angle of 60° by using a digital variable gloss meter UGV-5D manufactured by Suga Test Instruments Co., Ltd. in accordance with JIS K7105-1981. The results are given in Tables 2, 4, 7, and 9.

### 4) Method of Natural Snow Exposure Test

A test coated film was mounted at an angle of 30% with respect to the horizontal plane to an exposure stage placed in Teine-ku, Sapporo-shi, and the degree of snow accumulation (area ratio of snow accumulation) on the test coated film was observed visually and evaluated on a 11-graded scale on which a case of having no snow accumulation was rated as “0” and a case of having entire snow accumulation was rated as “10.” The results are given in Tables 2, 4, 7, and 9.

### 5) Air Conditioning Effect Caused by Water Film

A model barn made of plywood having a bottom surface of 1 m on each side and being 1 m in height was placed in Teine-ku, Sapporo-shi and the inside of the bottom surface and four side walls were insulated with foamed sheet. A layered article was mounted to the top of the test model at an angle of 30% with respect to the horizontal plane, and tap water was sprinkled intermittently with a sprinkler. The sprinkled amount of water was adjusted to 10 L/min. Regarding a sprinkling interval, after 9 a.m., water was sprinkled for three minutes and then water sprinkling was stopped for 27 minutes in one cycle. The temperature at a space center of the inside of the model barn was measured after a lapse of two cycles, after a lapse of four cycles, and after a lapse of six cycles. The results are given in Table 5.

TABLE 1

| | | | | | | Coefficient | |
|---|---|---|---|---|---|---|---|
| | | | | | | of | |
| | | | | | | dynamic | Contact |
| | Substrate | ST-UP | ST-XS | ST-ZL | Water | friction | angle |
| Example 1 | A | 10 | 5 | 5 | 80 | 0.05 | 1 |
| Example 2 | A | 5 | 10 | 5 | 80 | 0.06 | 2 |
| Example 3 | A | 5 | 5 | 7.5 | 82.5 | 0.06 | 2 |
| Comparative | A | 0 | 0 | 12.5 | 87.5 | 0.57 | 12 |
| Example 1 | | | | | | | |
| Comparative | A | 25 | 0 | 0 | 75 | 1.27 | 22 |
| Example 2 | | | | | | | |
| Comparative | A | 15 | 10 | 0 | 75 | 0.88 | 16 |
| Example 3 | | | | | | | |
| Comparative | A | 15 | 0 | 5 | 80 | 0.75 | 14 |
| Example 4 | | | | | | | |
| Comparative | A | 0 | 15 | 5 | 80 | 0.57 | 12 |
| Example 5 | | | | | | | |
| Comparative | A | 10 | 10 | 2.5 | 77.5 | 0.19 | 6 |
| Example 6 | | | | | | | |
| Comparative | A | 5 | 15 | 2.5 | 77.5 | 0.33 | 8 |
| Example 7 | | | | | | | |

TABLE 2

| | Gloss | | Test of exposure |
|---|---|---|---|
| | Initial | After 10 months | to natural snow |
| Example 1 | 1.00 | 1.00 | 0 |
| Comparative Example 1 | 1.00 | 0.66 | 8 |

TABLE 3

| | | | | | | Coefficient | |
|---|---|---|---|---|---|---|---|
| | | | | | | of | |
| | | | | | | dynamic | Contact |
| | Substrate | ST-UP | ST-XS | ST-ZL | Water | friction | angle |
| Example 4 | B | 10 | 5 | 5 | 80 | 0.05 | 1 |
| Example 5 | B | 5 | 10 | 5 | 80 | 0.07 | 2 |
| Example 6 | B | 5 | 5 | 7.5 | 82.5 | 0.07 | 2 |
| Comparative | B | 0 | 0 | 12.5 | 87.5 | 0.60 | 12 |
| Example 8 | | | | | | | |
| Comparative | B | 25 | 0 | 0 | 75 | 1.35 | 22 |
| Example 9 | | | | | | | |
| Comparative | B | 15 | 10 | 0 | 75 | 0.93 | 16 |
| Example 10 | | | | | | | |
| Comparative | B | 15 | 0 | 5 | 80 | 0.80 | 14 |
| Example 11 | | | | | | | |
| Comparative | B | 0 | 15 | 5 | 80 | 0.61 | 12 |
| Example 12 | | | | | | | |
| Comparative | B | 10 | 10 | 2.5 | 77.5 | 0.20 | 6 |
| Example 13 | | | | | | | |
| Comparative | B | 5 | 15 | 2.5 | 77.5 | 0.35 | 8 |
| Example 14 | | | | | | | |

TABLE 4

| | Gloss | | Test of exposure |
|---|---|---|---|
| | Initial | After 10 months | to natural snow |
| Example 4 | 1.0 | 1.0 | 0 |
| Comparative Example 8 | 1.0 | 0.6 | 8 |

TABLE 5

| | Temperature | | |
|---|---|---|---|
| | After a lapse of | After a lapse of | After a lapse of |
| | 2 cycles | 4 cycles | 6 cycles |
| Example 4 | 29° C. | 35° C. | 37° C. |
| Comparative | 31° C. | 37° C. | 39° C. |
| Example 8 | | | |
| Outdoor temperature | 27° C. | 30° C. | 31° C. |

TABLE 6

| | | | | | | Coefficient | |
|---|---|---|---|---|---|---|---|
| | | | | | | of | |
| | | | | | | dynamic | Contact |
| | Substrate | ST-UP | ST-XS | ST-ZL | Water | friction | angle |
| Example 7 | C | 10 | 5 | 5 | 80 | 0.08 | 2 |
| Example 8 | C | 5 | 10 | 5 | 80 | 0.09 | 3 |
| Example 9 | C | 5 | 5 | 7.5 | 82.5 | 0.09 | 3 |
| Comparative | C | 0 | 0 | 12.5 | 87.5 | 0.70 | 14 |
| Example 15 | | | | | | | |
| Comparative | C | 25 | 0 | 0 | 75 | 1.53 | 25 |
| Example 16 | | | | | | | |
| Comparative | C | 15 | 10 | 0 | 75 | 1.07 | 18 |
| Example 17 | | | | | | | |
| Comparative | C | 15 | 0 | 5 | 80 | 0.91 | 16 |
| Example 18 | | | | | | | |
| Comparative | C | 0 | 15 | 5 | 80 | 0.70 | 14 |
| Example 19 | | | | | | | |
| Comparative | C | 10 | 10 | 2.5 | 77.5 | 0.25 | 7 |
| Example 20 | | | | | | | |
| Comparative | C | 5 | 15 | 2.5 | 77.5 | 0.41 | 10 |
| Example 21 | | | | | | | |

TABLE 7

| | Gloss | | Test of exposure |
|---|---|---|---|
| | Initial | After 10 months | to natural snow |
| Example 7 | 0.4 | 0.4 | 0 |
| Comparative Example 15 | 0.4 | 0.2 | 8 |

TABLE 8

| | | | | | | Coefficient | |
|---|---|---|---|---|---|---|---|
| | | | | | | of | |
| | | | | | | dynamic | Contact |
| | Substrate | ST-UP | ST-XS | ST-ZL | Water | friction | angle |
| Example 10 | D | 10 | 5 | 5 | 80 | 0.05 | 1 |
| Example 11 | D | 5 | 10 | 5 | 80 | 0.07 | 2 |
| Example 12 | D | 5 | 5 | 7.5 | 82.5 | 0.07 | 2 |
| Comparative | D | 0 | 0 | 12.5 | 87.5 | 0.60 | 12 |
| Example 22 | | | | | | | |
| Comparative | D | 25 | 0 | 0 | 75 | 1.35 | 22 |
| Example 23 | | | | | | | |
| Comparative | D | 15 | 10 | 0 | 75 | 0.93 | 16 |
| Example 24 | | | | | | | |
| Comparative | D | 15 | 0 | 5 | 80 | 0.80 | 14 |
| Example 25 | | | | | | | |
| Comparative | D | 0 | 15 | 5 | 80 | 0.61 | 12 |
| Example 26 | | | | | | | |
| Comparative | D | 10 | 10 | 2.5 | 77.5 | 0.20 | 6 |
| Example 27 | | | | | | | |
| Comparative | D | 5 | 15 | 2.5 | 77.5 | 0.35 | 8 |
| Example 28 | | | | | | | |

TABLE 9

| | Gloss | | Test of exposure |
|---|---|---|---|
| | Initial | After 10 months | to natural snow |
| Example 10 | 1.0 | 1.0 | 0 |
| Comparative Example 22 | 1.0 | 0.6 | 8 |

What is claimed is:

1. A layered article comprising a substrate and a particle layer laminated on the substrate, wherein the particle layer is a layer formed by applying a particle dispersion liquid to the substrate, the particle dispersion liquid comprising:
first silicon oxide particles composed of branched rod-shaped particles, each of the branched rod-shaped particles having a diameter of 3 to 50 nm and the branched rod-shaped particles having an average particle diameter of 30 to 500 nm,
second silicon oxide particles having an average particle diameter of 1 to 20 nm,
third silicon oxide particles having an average particle diameter of greater than 20 nm, and
a dispersion medium,
wherein the content of the first silicon oxide particles is 15 to 50% by weight, the content of the second silicon oxide particles is 15 to 50% by weight, and the content of the third silicon oxide particles is 35 to 70% by weight where the total amount of the first, second and third silicon oxide particles is 100% by weight, and then removing the dispersion medium from the applied particle dispersion liquid.

2. The layered article according to claim 1, wherein the particle layer has a water contact angle of smaller than 5°.

3. The layered article according to claim 1, wherein the substrate is a film made of a thermoplastic resin.

4. The layered article according to claim 1, wherein the substrate is a signboard for outdoor use.

5. The layered article according to claim 1, wherein the substrate is glass.

6. A layered article comprising a substrate and a particle layer laminated on the substrate, wherein the particle layer comprises:
first silicon oxide particles composed of branched rod-shaped particles, each of the branched rod-shaped particles having a diameter of 3 to 50 nm and the branched rod-shaped particles having an average particle diameter of 30 to 500 nm,
second silicon oxide particles having an average particle diameter of 1 to 20 nm, and
third silicon oxide particles having an average particle diameter of greater than 20 nm,
wherein the content of the first silicon oxide particles is 15 to 50% by weight, the content of the second silicon oxide particles is 15 to 50% by weight, and the content of the third silicon oxide particles is 35 to 70% by weight where the total amount of the first, second and third silicon oxide particles in the particle layer is 100% by weight.

7. A solar panel having a light receiving surface, wherein the light receiving surface is composed of the layered article according to claim 5 with the particle layer exposed to the outside of the solar panel.
